(19) United States
(12) Patent Application Publication
(10) Pub. No.: US 2025/0185457 A1
(43) Pub. Date: Jun. 5, 2025

(54) LIGHT-EMITTING DEVICE AND MANUFACTURING METHOD THEREFOR

(71) Applicant: Sharp Display Technology Corporation, Kameyama City, Mie (JP)

(72) Inventor: HISAYUKI UTSUMI, Kameyama City, Mie (JP)

(21) Appl. No.: 18/861,994

(22) PCT Filed: Jun. 30, 2022
(86) PCT No.: PCT/JP2022/026182

§ 371 Date: Oct. 31, 2024

(51) Int. Cl. H10K 50/842; C09J 11/06; H10K 50/115

(52) U.S. Cl. CPC H10K 50/8426; C09J 11/06; H10K 50/115; H10K 50/8428

(57) ABSTRACT

A light-emitting device includes a substrate, at least one light-emitting element provided on the substrate, a cover member that covers the at least one light-emitting element, and an adhesive layer that is provided between the substrate and the cover member, surrounds the light-emitting element, and bonds a peripheral portion of the cover member to the substrate. The adhesive layer contains a curable adhesive, a spacer, and an oxygen adsorbent.

### TECHNICAL FIELD

The disclosure relates to a light-emitting device and a method for manufacturing the light-emitting device.

### BACKGROUND ART

Influence of moisture, oxygen, or the like degrades light-emission characteristics of light-emitting elements such as quantum dot light emitting diodes (QLEDs) and organic light emitting diodes (OLEDs). In particular, quantum dots and organic matter used in light-emitting elements are known to be degraded by oxygen, and the degradation by oxygen reduces luminous efficiency of the light-emitting elements. Therefore, in order to suppress the influence of moisture, oxygen, or the like, the light-emitting element is sealed with a cover member such as a cover glass.

However, when the light-emitting element is sealed in the atmosphere, oxygen enters the cover member, causing degradation in the light-emission characteristics. Thus, even when such light-emitting devices are manufactured in an inert atmosphere, it is not easy to prevent oxygen from entering for a long period of time.

Therefore, for example, in PTL 1, when an organic electroluminescence (EL) structure (OLED) formed on a substrate is sealed with a cover-shaped sealing member using an adhesive, a countermeasure is taken in which a porous adsorption sheet is attached to an upper inner surface of the sealing member with an adhesive.

PTL 1 discloses that the porous adsorption sheet can be formed by extruding a mixture of a binder resin and a hygroscopic adsorbent into a sheet shape and may contain an oxygen adsorbent. In PTL 1, a mixture of a chemical adsorbent and activated carbon is preferably used as the hygroscopic adsorbent, and powder of a metal or metal oxide such as iron powder or iron oxide is used as the oxygen adsorbent.

### CITATION LIST

### Patent Literature

PTL 1: JP 2002-280166 A

### SUMMARY OF INVENTION

### Technical Problem

However, when such a porous adsorption sheet is attached to the upper inner surface of the sealing member, the porous adsorption sheet blocks transmission of light when light is emitted from a sealing member side, which interferes with luminescence observation.

In addition, in order to industrially manufacture such light-emitting devices in an inert atmosphere, investment in equipment is required, and adjustment and maintenance of a working environment are required, which increases manufacturing costs.

An aspect of the disclosure has been made in view of the above problems, and an object of the disclosure is to provide a light-emitting device that can suppress a decrease in luminous efficiency even when manufactured in the atmosphere, can be manufactured in the atmosphere, and does not interfere with luminescence observation, and a method for manufacturing the light-emitting device.

### Solution to Problem

In order to solve the above problems, a light-emitting device according to an aspect of the disclosure includes a substrate, at least one light-emitting element provided on the substrate, a cover member having light transmitting property and configured to cover the at least one light-emitting element, and an adhesive layer provided between the substrate and the cover member, surrounding the at least one light-emitting element, and configured to bond a peripheral portion of the cover member to the substrate, in which the adhesive layer contains a curable adhesive, a spacer, and an oxygen adsorbent.

In order to solve the above problems, a method for manufacturing a light-emitting device according to an aspect of the disclosure, the light-emitting device includes a substrate, a light-emitting element provided on the substrate, a cover member having light transmitting property and configured to cover the light-emitting element, and an adhesive layer provided between the substrate and the cover member, surrounding the light-emitting element, and configured to bond a peripheral portion of the cover member to the substrate, the method includes applying an adhesive layer material containing a curable adhesive, a spacer, and an oxygen adsorbent to the substrate or the cover member in the atmosphere, and bonding the substrate and the cover member in the atmosphere with an adhesive layer made of the adhesive layer material as the adhesive layer interposed between the substrate and the cover member by curing the curable adhesive.

### Advantageous Effects of Invention

According to an aspect of the disclosure, it is possible to provide a light-emitting device that can suppress a decrease in external quantum efficiency even when manufactured in the atmosphere, can be manufactured in the atmosphere, and does not interfere with luminescence observation, and a method for manufacturing the light-emitting device.

### BRIEF DESCRIPTION OF DRAWINGS

FIG. 1 is a cross-sectional view illustrating an example of a schematic configuration of a light-emitting device according to a first embodiment.

FIG. 2 is a cross-sectional view illustrating a schematic configuration of the light-emitting element illustrated in FIG. 1.

FIG. 3 is a plan view illustrating an example of a schematic configuration of the light-emitting device according to the first embodiment.

FIG. 4 is a flowchart illustrating an example of a method for manufacturing the light-emitting device according to the first embodiment.

FIG. 5 is a flowchart illustrating an example of a method for forming the light-emitting element illustrated in FIG. 2.

FIG. 6 is a cross-sectional view illustrating an example of a schematic configuration of the light-emitting device according to a third modified example of the first embodiment.

FIG. 7 is a plan view illustrating a schematic configuration of a display device according to a second embodiment.

FIG. 8 is a cross-sectional view illustrating an example of a schematic configuration of the display device according to the second embodiment.

FIG. 9 is a cross-sectional view illustrating an example of a schematic configuration of a display region of the display device illustrated in FIG. 8.

### DESCRIPTION OF EMBODIMENTS

### First Embodiment

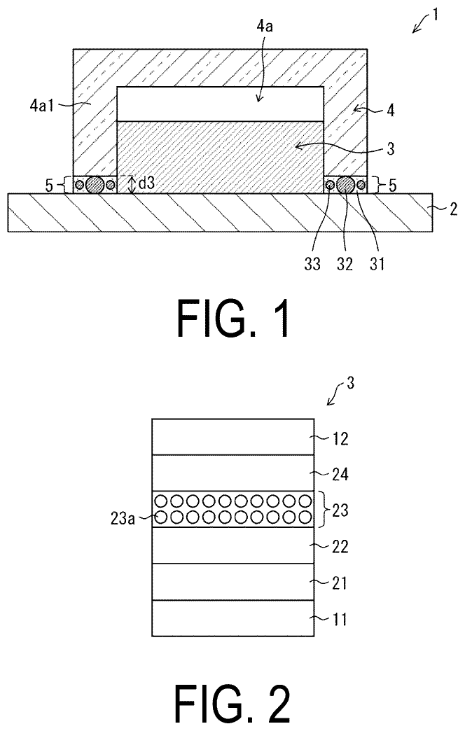

An embodiment of the disclosure will be described as follows with reference to FIG. 1 to FIG. 6. Note that, in the following, description of “from A to B” for two numbers A and B means “being equal to or greater than A and equal to or less than B”, unless otherwise specified. Further, in the following, a layer formed in a process prior to that of a layer being compared is referred to as a “lower layer,” and a layer formed in a process after that of a layer being compared is referred to as an “upper layer”. Thus, hereinafter, a direction from a substrate toward a cover member is referred to as an upward direction, and a direction from the cover member toward the substrate is referred to as a downward direction.

### Light-Emitting Device

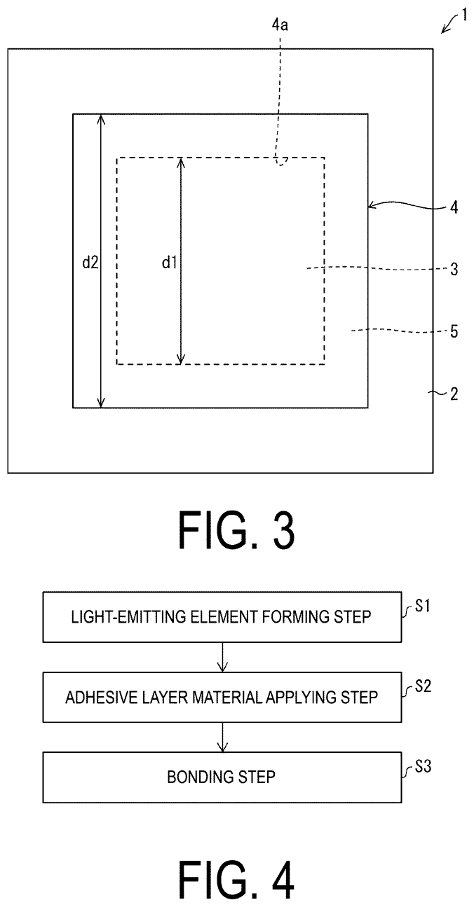

FIG. 1 is a cross-sectional view illustrating an example of a schematic configuration of a light-emitting device 1 according to the present embodiment. FIG. 2 is a cross-sectional view illustrating a schematic configuration of a light-emitting element 3 illustrated in FIG. 1. FIG. 3 is a plan view illustrating an example of a schematic configuration of the light-emitting device 1 according to the present embodiment.

As illustrated in FIG. 1, the light-emitting device 1 according to the present embodiment includes a substrate 2, a light-emitting element 3 provided on the substrate 2, a cover member 4 that covers the light-emitting element 3, and an adhesive layer 5 provided between the substrate 2 and the cover member 4.

The substrate 2 is a support body for supporting the light-emitting element 3 and the cover member 4 and for forming layers included in the light-emitting element 3. The substrate 2 may be, for example, a rigid inorganic substrate such as a glass substrate, or a flexible substrate containing a resin such as polyimide as a main component. The substrate 2 may be provided with thin film transistors (TFTs), capacitance elements, and the like (not illustrated).

The light-emitting element 3 includes a first electrode, a second electrode, and function layers provided between the first electrode and the second electrode. In the disclosure, layers between the first electrode and the second electrode are referred to as function layers. At least a light-emitting layer is included as a function layer. Hereinafter, the “light-emitting layer” will be referred to as “EML”. The light-emitting element 3 may be a single-layer type including only one EML as a function layer, or may be a multi-layer type including a plurality of function layers as function layers. Examples of the function layers other than the EML include a hole injection layer, a hole transport layer, and an electron transport layer. Hereinafter, the hole injection layer will be referred to as “HIL”, the hole transport layer will be referred to as “HTL”, and the electron transport layer will be referred to as “ETL”.

One of the first electrode and the second electrode is an anode electrode, another is a cathode electrode. The light-emitting element 3 may have a conventional structure in which the anode electrode is a lower layer electrode and the cathode electrode is an upper layer electrode, or may have an inverted structure in which the cathode electrode is a lower layer electrode and the anode electrode is an upper layer electrode.

As an example, as illustrated in FIG. 2, the light-emitting element 3 has a conventional structure in which an anode electrode 11 is a lower layer electrode and a cathode electrode 12 is an upper layer electrode, and has a configuration in which the anode electrode 11, function layers including an EML 23, and the cathode electrode 12 are provided in this order from a lower layer side. The light-emitting element 3 illustrated in FIG. 2 includes, for example, an HIL 21, an HTL 22, the EML 23, and an ETL 24 as function layers, and has a configuration in which the anode electrode 11, the HIL 21, the HTL 22, the EML 23, the ETL 24, and the cathode electrode 12 are provided in this order from the lower layer side.

However, the configuration of the light-emitting element 3 is not limited thereto, and may have an inverted structure in which the cathode electrode 12 is a lower layer electrode and the anode electrode 11 is an upper layer electrode. In this case, the layering order of the function layers is reversed from that in FIG. 2. In other word, the light-emitting element 3 may have a configuration in which the cathode electrode 12, the ETL 24, the EML 23, the HTL 22, the HIL 21, and the anode electrode 11 are layered in this order from the lower layer side. The light-emitting element 3 may have a configuration in which at least one of the function layers other than the EML 23 is not provided, or may include a function layer other than the above function layers.

In the following, a case where the light-emitting element 3 is a QLED will be described as an example. However, the light-emitting element 3 is not limited thereto, and may be, for example, an OLED.

The anode electrode 11 is an electrode that supplies holes to the EML 23 when a voltage is applied. The cathode electrode 12 is an electrode that supplies electrons to the EML 23 when a voltage is applied. The anode electrode 11 and the cathode electrode 12 each contain a conductive material, and are connected to a power supply (not illustrated), so that a voltage is applied therebetween.

Of the anode electrode 11 and the cathode electrode 12, the electrode on the light extraction surface side of the light-emitting element 3 needs to be light-transmitting. The anode electrode 11 and the cathode electrode 12 may each be a single layer or may each have a layered structure.

The light-emitting device 1 according to the disclosure is a top emission light-emitting device in which light is emitted from a cover member 4 side, and the light-emitting element 3 emits light to the outside from an upper layer electrode side. Thus, in the light-emitting element 3, a light-transmissive electrode having light transmitting property is used for the upper layer electrode, and a so-called reflective electrode having light reflectivity is used for the lower layer electrode. Accordingly, in the example illustrated in FIG. 2, a light-transmissive electrode is used as the cathode electrode 12, and a reflective electrode is used as the anode electrode 11.

The light-transmissive electrode is formed of a light-transmissive material such as indium tin oxide (ITO), indium zinc oxide (IZO), silver nanowire (AgNW), a thin film of magnesium-silver (MgAg) alloy, or a thin film of silver (Ag), for example.

The reflective electrode may be formed of a light-reflective material, for example, a metal such as Ag or aluminum (Al), or an alloy containing these metals, or may be formed by layering a light-transmissive material and a light-reflective material. Accordingly, the reflective electrode may have a layered structure such as ITO/Ag alloy/ITO, ITO/Ag/ITO, or Al/IZO.

The EML 23 is a layer that contains a light-emitting material and emits light by recombination of holes transported from the anode electrode 11 and electrons transported from the cathode electrode 12. The light-emitting element 3 according to the present embodiment is a QLED as described above, and the EML 23 contains nano-sized quantum dots (hereinafter, referred to as “QDs”) 23a corresponding to a luminescent color as a light-emitting material.

The QDs 23a are dots composed of nanoparticles with a maximum width of 100 nm or less. QDs generally have a composition derived from a semiconductor material, and thus may also be called semiconductor nanoparticles. Furthermore, since QDs have a specific crystal structure, for example, they may also be called nanocrystals.

A shape of the QDs 23a is not restricted as long as it satisfies the above maximum width, and is not limited to a spherical three-dimensional shape (circular cross-sectional shape). The shape of the QDs 23a may be, for example, a polygonal cross-sectional shape, a rod-like three-dimensional shape, a branch-like three-dimensional shape, or a three-dimensional shape having unevenness on the surface thereof, or a combination thereof.

The QDs 23a may be of a core type, or a core-shell type or a core-multishell type including a core and a shell. When the QD 23a includes a shell, it is sufficient that the core is located in the center and the shell is provided on the surface of the core. Although it is desirable for the shell to cover the entire core, the shell need not necessarily completely cover the core. The QDs 23a may be of a two-component core type, a three-component core type, or a four-component core type. Note that the QDs 23a may contain doped nanoparticles, or may have a compositionally graded structure.

The core may be formed of, for example, Si, Ge, CdSe, CdS, CdTe, InP, GaP, InN, ZnSe, ZnS, ZnTe, CdSeTe, GaInP, ZnSeTe, or the like. The shell may be formed of, for example, CdS, ZnS, CdSSe, CdTeSe, CdSTe, ZnSSe, ZnSTe, ZnTeSe, AIP, or the like.

The QDs 23a can have light emission wavelengths changed in various ways depending on, for example, particle sizes and compositions thereof. The QDs 23a are QDs that emit visible light, and can achieve, for example, red light, green light, or blue light by appropriately adjusting the particle size and composition of the QDs 23a.

The HIL 21 has hole transport properties and promotes injection of holes from the anode electrode 11 to the HTL 22. The HTL 22 has hole transport properties and transports the holes injected from the HIL 21 to the EML 23. The HIL 21 and the HTL 22 contain hole transport materials, respectively. Known hole transport materials can be used as these hole transport materials.

The hole transport material used in the HIL 21 is not limited, and examples thereof include a composite of poly(3,4-ethylenedioxythiophene)(PEDOT) and poly(4-styrenesulfonate) (PSS), known as PEDOT: PSS. Only one type of the above hole transport material may be used, or a mixture of two or more types may be used as appropriate.

The hole transport material used in the HTL 22 is not limited, and examples thereof include poly [(9,9-dioctylfluorenyl-2,7-diyl)-co-(4,4′-(N-4-sec-butylphenyl))diphenylamine)] referred to as “TFB”, poly [N,N′-bis(4-butylphenyl)-N,N′-bis(phenyl)-benzidine] referred to as “p-TPD”, and polyvinyl carbazole referred to as “PVK”. These hole transport materials may also be used as only one type, or a mixture of two or more types as appropriate.

The ETL 24 has electron transport properties and transports electrons injected from the cathode electrode 12 to the EML 23. The ETL 24 contains an electron transport material. Any of known electron transport materials can be used as the electron transport material.

An electron transport material used in the ETL 24 is not limited, and examples thereof include N-type oxide semiconductor nanoparticles such as ZnO nanoparticles and MgZnO nanoparticles. Since these N-type oxide semiconductor nanoparticles have excellent electron injection properties, an electron injection layer is often omitted as illustrated in FIG. 2.

The light-emitting element 3 is formed on the substrate 2 as described above, and is sealed with the substrate 2 and the cover member 4 positioned to face the substrate 2 in order to protect the light-emitting element 3 by suppressing entry of foreign matter such as moisture and oxygen into the light-emitting element 3.

The cover member 4 has, for example, a recessed shape with a recessed portion 4a provided in a central portion facing the substrate 2. The recessed portion 4a is formed larger than the light-emitting element 3 so that the light-emitting element 3 can be placed therein.

Note that FIG. 2 illustrates an example in which the cover member 4 has the recessed portion 4a into which the light-emitting element 3 fits in a plan view, and the recessed portion 4a has approximately the same size as a periphery of the light-emitting element 3 in a plan view. However, the recessed portion 4a need only be capable of placing the light-emitting element 3 inside, and a gap may be provided between an inner side wall forming the recessed portion 4a and the light-emitting element 3. A depth of the recessed portion 4a is not limited, but is preferably greater than or equal to a thickness of the light-emitting element 3 in order to safely accommodate and seal the light-emitting element 3.

As described above, the light-emitting device 1 according to the present embodiment is a top emission light-emitting device that emits light from the cover member 4 side to the outside. Thus, a cover member having light transmitting property is used as the cover member 4. As the cover member 4, for example, a recessed sealing member made of glass, called a cover glass, is used.

Glass has excellent visible light transmittance and low moisture and oxygen transmittance, which suppresses entry of moisture and oxygen in the space in which the light-emitting element 3 is sealed.

As illustrated in FIG. 1 and FIG. 3, the adhesive layer 5 is provided between the substrate 2 and the cover member 4 so as to surround the light-emitting element 3. The peripheral portion of the cover member 4 is bonded to the substrate 2 with the adhesive layer 5.

The adhesive layer 5 contains a curable adhesive 31, a spacer 32, and an oxygen adsorbent 33. The adhesive layer 5 contains the curable adhesive 31 as an adhesive for bonding the substrate 2 and the cover member 4. By curing the curable adhesive 31, the substrate 2 and the cover member 4 can be bonded (joined).

The curable adhesive 31 may be a photo-curable adhesive or a thermosetting adhesive, but is preferably a photo-curable adhesive. Thus, as the curable adhesive 31, for example, a photo-curable compound that can be polymerized (photopolymerized) and cured (photo-cured) by light (active energy rays) such as ultraviolet rays (UV) or by action of the light and a photopolymerization initiator is preferably used. Thus, as the curable adhesive 31, for example, a photo-curable adhesive such as a bisphenol epoxy resin is preferably used.

For curing the curable adhesive 31, a polymerization initiator such as a photopolymerization initiator may be used. Thus, the curable adhesive 31 in the adhesive layer 5, that is, the cured curable adhesive 31, may contain a polymerization initiator such as a photopolymerization initiator used for curing the curable adhesive 31. By containing a polymerization initiator such as a photopolymerization initiator in the curable adhesive 31, it is possible to promote polymerization and curing of the curable compound such as the photo-curable compound when forming the adhesive layer 5.

The polymerization initiator is not limited as long as it can initiate polymerization of the curable compound by irradiation with light such as UV. As the polymerization initiator, various known polymerization initiators can be used, and an appropriate one is selected depending on a type of the curable compound.

An amount of the polymerization initiator to be mixed is not limited, and may be appropriately set depending on, for example, a type of the curable adhesive 31. The amount of the polymerization initiator to be mixed can be set in the same manner as when the adhesive layer 5 does not contain the spacer 32 or the oxygen adsorbent 33. For example, as illustrated in Examples described later, the polymerization initiator is used in an amount of about 1% relative to the curable adhesive 31.

The adhesive layer 5 contains the oxygen adsorbent 33 and also contains the spacer 32 for keeping a distance between the substrate 2 and the cover member 4 constant, as described above.

By containing the oxygen adsorbent 33 in the adhesive layer 5, it is possible to suppress or prevent entry of oxygen into the space between the substrate 2 and the cover member 4 in which the light-emitting element 3 is sealed, and it is also possible to adsorb oxygen that has entered the sealed space during the manufacturing process of the light-emitting device 1. Thus, an adverse effect of oxygen on the light-emission characteristics of the light-emitting element 3 can be suppressed.

By containing the spacer 32 in the adhesive layer 5, the adhesive layer between the substrate 2 and the cover member 4 can be maintained at a constant thickness. Thus, by containing the spacer 32 in the adhesive layer 5, uniformity of bonding between the substrate 2 and the cover member 4 can be improved. The spacer 32 ensures a sufficient thickness for the adhesive layer 5, so that the adhesive layer 5 can contain a sufficient amount of the oxygen adsorbent 33 required for adsorbing oxygen in the light-emitting device 1. Thus, the amount of the oxygen adsorbent 33 contained in the adhesive layer 5 can be adjusted by the spacer 32, and an area of the oxygen adsorbent 33 with which oxygen can come into contact (in other words, an area where oxygen is captured by the oxygen adsorbent 33) can be sufficiently ensured. This makes it possible to provide the light-emitting device 1 that can suppress a decrease in luminous efficiency even when manufactured in the atmosphere and can be manufactured in the atmosphere.

The spacer 32 is desirably made of a material having high hygroscopicity, although there is no particular limitation to the material, and for example, silica or the like is suitably used.

The thickness of the adhesive layer 5 between the substrate 2 and the cover member 4 is determined by a height of the spacer 32 (a thickness in a layering direction of the light-emitting element 3). The height of the spacer 32 may be set so as to ensure a desired area for capturing oxygen by the oxygen adsorbent 33, depending on the amount of the oxygen adsorbent 33 relative to the curable adhesive 31, the content of the light-emitting material in the light-emitting element 3, and the like, and is not limited to any particular height.

A shape of the spacer 32 is not limited, and may be appropriately selected depending on strength, the desired height of the spacer 32, ease of forming the adhesive layer 5, and the like. In the present embodiment, as illustrated in Examples to be described later, as an example, filler composed of spherical monodispersed silica particles having a diameter of 12 μm is used for the spacer 32. Thus, the adhesive layer 5 having a thickness of 12 μm is formed between the substrate 2 and the cover member 4. Although the shape of the spacer 32 is not limited, by using the spherical filler for the spacer 32 in this way, the adhesive layer 5 having a uniform thickness can be easily formed by simply mixing the filler with the adhesive layer material for forming the adhesive layer 5, and applying and curing the adhesive material.

As described above, in the light-emitting device 1 according to the present embodiment, the oxygen adsorbent 33 is contained in the adhesive layer 5. Thus, the oxygen adsorbent 33 does not hinder the transmission of light as in the case where the oxygen adsorbent is provided in the space in which the light-emitting element is sealed as in PTL 1, and thus does not interfere the luminescence observation.

Accordingly, various conventionally known oxygen adsorbents can be used as the oxygen adsorbent 33, and although there is no particular limitation, a phenol-based oxygen adsorbent is preferable.

The phenol-based oxygen adsorbent has excellent thermal stability. By using the phenol-based oxygen adsorbent among the oxygen adsorbents, it is possible to obtain the light-emitting device 1 that is more excellent in the effect of suppressing or preventing a decrease in external quantum efficiency.

In particular, as the oxygen adsorbent 33, for example, at least one phenol-based oxygen adsorbent selected from the group consisting of dibutylhydroxytoluene (BHT), 2,6-di-tert-butyl-4-methoxyphenol, 3-tert-butyl-4-hydroxyanisole, hydroquinone, hydroquinone monomethyl ether, and 4-tert-butylcatechol is more preferably used. By using these oxygen adsorbents among the phenol-based oxygen adsorbents, it is possible to obtain the light-emitting device 1 that is even more excellent in the effect of suppressing or preventing a decrease in external quantum efficiency.

Among these phenol-based oxygen adsorbents, BHT is particularly preferable because it has a high effect of suppressing or preventing a decrease in external quantum efficiency of the light-emitting element.

An oxygen adsorption mechanism of the oxygen adsorbent 33 will be described below.

For example, oxidation of organic matter contained in the light-emitting element 3 proceeds through a radical chain reaction described below.

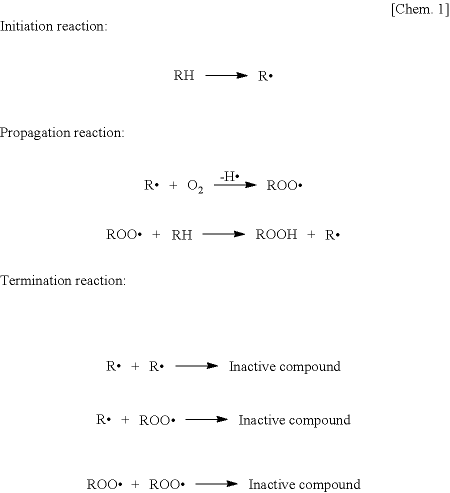

As shown in the above reaction formulae, in an initiation reaction, a hydrogen radical (hydrogen atom, H·) is released from organic matter (RH) such as polyolefin due to heat or light, generating a free radical (R·) such as an alkyl radical.

In a propagation reaction, in the presence of oxygen, R· reacts with oxygen to produce a peroxy radical (ROO·). ROO· extracts hydrogen from RH to produce R·, and ROO· itself becomes a hydroperoxide (ROOH). Then, the generated R· reacts with oxygen to generate a peroxy radical (ROO·). This reaction is a chain reaction, and as it repeats, deterioration of the organic matter due to oxidation progresses. In a termination reaction, radicals react with each other to form an inactive compound.

The oxygen adsorbent 33 captures ROO· in the propagation reaction, and stops the chain reaction as shown in the following formulae. The following formulae show an example in which the oxygen adsorbent 33 is a phenol-based oxygen adsorbent (ArOH) such as BHT.

ROO·+Ar OH→ROOH+ArO·

ROO·+ArO·→Non-radical chemical species [Chem. 2]

As shown in the above reaction formulae, ArOH, for example as a hydrogen donor, gives hydrogen to ROO· generated through the propagation reaction to convert ROO· to ROOH, and ArOH itself becomes ArO·. ArO· is a stable radical and does not generate a new radical. This tendency is remarkable when the —OH group is protected with a bulky substituent, such as in BHT. ArO· generated by the above reaction reacts with ROO· to form a non-radical chemical species. Thus, the chain reaction is stopped.

When oxygen is present in the system, the QDs cause energy transfer to the oxygen in the system and QDs themselves are oxidized. When such a reaction occurs repeatedly, non-luminescent oxides form islands on the surfaces of the QDs, gradually reducing the emission intensity of the QDs. The oxygen adsorbent 33 prevents oxidation of the QDs by capturing (adsorbing) oxygen.

Thus, conventional light-emitting elements need to be manufactured in an inert atmosphere, but according to the present embodiment, the adhesive layer 5 contains the oxygen adsorbent 33 as described above, so that the oxygen adsorbent 33 can adsorb oxygen that has entered the space in which the light-emitting element 3 is sealed. Thus, an adverse effect of oxygen on the light-emission characteristics of the light-emitting element can be suppressed.

The amount of the oxygen adsorbent 33 relative to the curable adhesive 31 in the adhesive layer 5 may be, for example, 3 wt. % or more as illustrated in Examples described later, but is preferably 5 wt. % or more, and more preferably 20 wt. % or more. However, when the amount of the oxygen adsorbent 33 contained in the adhesive layer 5, in particular, the amount of the oxygen adsorbent 33 relative to the curable adhesive 31, is increased, the reliability test result tends to be poor, although a decrease in external quantum efficiency when the light-emitting device 1 is produced in the atmosphere can be suppressed. Thus, the amount of the oxygen adsorbent 33 relative to the curable adhesive 31 is preferably, for example, 50 wt. % or less as illustrated in Examples described later, and more preferably 40 wt. % or less.

In particular, when the amount of the oxygen adsorbent 33 relative to the curable adhesive 31 in the adhesive layer 5 is from 5 wt. % to 40 wt. %, the light-emitting device 1 can be obtained that has a higher effect of suppressing or preventing a decrease in external quantum efficiency, can be manufactured in the atmosphere, and is more reliable. When the amount of the oxygen adsorbent 33 relative to the curable adhesive 31 is from 20 wt. % to 40 wt. %, it is possible to obtain the light-emitting device 1 that can obtain an external quantum efficiency that is almost equivalent to that obtained when a cell is produced in an inert atmosphere, has an even higher effect of suppressing or preventing a decrease in external quantum efficiency, can be manufactured in the atmosphere, and is even more reliable.

The adhesive layer 5 preferably contains the oxygen adsorbent 33 in an amount at least 2.7 times, and more preferably contains the oxygen adsorbent 33 in an amount at least 4.4 times, the weight of the light-emitting material in the light-emitting element 3.

As described above, in order to ensure a sufficient area for oxygen capture by the oxygen adsorbent 33, it is preferable that the adhesive layer 5 contain the spacer 32. Here, as illustrated in FIG. 3, a case where the light-emitting element 3 formed in a square shape with four sides measuring d1 in a plan view is sealed with the cover member 4 formed in a square shape with four sides measuring d2 in a plan view and having the recessed portion 4a into which the light-emitting element 3 fits in a plan view will be considered as an example. In this case, a coating area of the adhesive layer material used for forming the adhesive layer 5 is (d2×d2)−(d1×d1). Here, when a thickness of the adhesive layer 5 between the substrate 2 and the cover member 4 is d3 as illustrated in FIG. 1, d3 is equal to the height of the spacer 32 in the layering direction of the light-emitting element 3, and when spherical particles (filler) are used for the spacer 32, d3 is equal to the diameter of the spherical particles.

Here, as illustrated in Examples described later, d1=15 mm, d2=20 mm, d3=12 μm (=12×10⁻⁴ cm), and the light-emitting element 3 contains 2.15×10⁻⁵ g (0.02154 mg) of QDs as the light-emitting material.

At this time, the adhesive layer 5 contains, for example, 0.5 parts by weight (5 wt. %) of the spacer 32, 0.3 parts by weight (3 wt. %) of the oxygen adsorbent 33, and 0.1 parts by weight (1 wt. %) of the polymerization initiator relative to 10 g of the curable adhesive 31. It is assumed that the curable adhesive 31, the spacer 32, the oxygen adsorbent 33, and the polymerization initiator have the same specific gravity. In this case, the amount of the oxygen adsorbent 33 contained in the adhesive layer 5 is 0.0000578 g (=0.0578 mg)(≈((2 cm×2 cm×12×10⁻⁴ cm)−(1.5 cm×1.5 cm×12×10⁻⁴ cm))×(0.3/(0.5+0.3+0.1+10))).

Further, the adhesive layer 5 contains, for example, 0.5 parts by weight (5 wt. %) of the spacer 32, 0.5 parts by weight (5 wt. %) of the oxygen adsorbent 33, and 0.1 parts by weight (1 wt. %) of the polymerization initiator relative to 10 g of the curable adhesive 31. As described above, it is assumed that the curable adhesive 31, the spacer 32, the oxygen adsorbent 33, and the polymerization initiator have the same specific gravity. In this case, the amount of the oxygen adsorbent 33 contained in the adhesive layer 5 is 0.0000946 g (=0.0946 mg)(≈((2 cm×2 cm×12×10⁻⁴ cm)−(1.5 cm×1.5 cm×12×10⁻⁴ cm))×(0.5/(0.5+0.5+0.1+10))).

Accordingly, when the amount of the oxygen adsorbent 33 relative to the curable adhesive 31 is 3 wt. %, the content of the oxygen adsorbent 33 in the adhesive layer 5 is 2.7 times the weight of the light-emitting material in the light-emitting element 3. When the amount of the oxygen adsorbent 33 relative to the curable adhesive 31 is 5 wt. %, the content of the oxygen adsorbent 33 in the adhesive layer 5 is 4.4 times the weight of the light-emitting material in the light-emitting element 3. Thus, as described above, the content of the oxygen adsorbent 33 in the adhesive layer 5 is preferably at least 2.7 times, and more preferably at least 4.4 times, the weight of the light-emitting material in the light-emitting element 3.

By containing the oxygen adsorbent 33 in the adhesive layer 5 in an amount at least 2.7 times the weight of the light-emitting material in the light-emitting element 3, oxidation of the light-emitting material can be sufficiently suppressed even when the light-emitting device 1 is manufactured in the atmosphere, and the light-emitting device 1 having a higher effect of suppressing or preventing a decrease in external quantum efficiency can be obtained. In addition, by containing the oxygen adsorbent 33 in the adhesive layer 5 in an amount at least 4.4 times the weight of the light-emitting material in the light-emitting element 3, the light-emitting device 1 can be obtained that has a higher effect of suppressing oxidation of the light-emitting material and an even higher effect of suppressing or preventing a decrease in external quantum efficiency.

### Method for Manufacturing Light-Emitting Device 1

Next, a method for manufacturing the light-emitting device 1 will be described.

FIG. 4 is a flowchart illustrating an example of a method for manufacturing the light-emitting device 1 according to the present embodiment.

In the method for manufacturing the light-emitting device 1 according to the present embodiment, first, as illustrated in FIG. 3, the light-emitting element 3 is formed on the substrate 2 (step S1, light-emitting element forming step).

Subsequently, the adhesive layer material containing the curable adhesive 31, the spacer 32, and the oxygen adsorbent 33 is applied to the substrate or the cover member so as to surround the light-emitting element and to match the peripheral portion of the cover member (step S2, adhesive layer material applying step).

Subsequently, the cover member is placed on the substrate with the adhesive layer material interposed therebetween, and the curable adhesive is cured. Thus, the substrate and the cover member are bonded with the adhesive layer made of the adhesive layer material interposed therebetween (step S3, bonding step).

In this way, the light-emitting device 1 can be manufactured that includes the substrate 2, the light-emitting element 3 provided on the substrate 2, the cover member 4 that covers the light-emitting element 3, and the adhesive layer 5 that is provided between the substrate 2 and the cover member 4, surrounds the light-emitting element 3, and bonds the peripheral portion of the cover member 4 to the substrate 2.

In the present embodiment, the series of steps from step S1 to step S3 can be performed in the atmosphere. As described above, according to the present embodiment, it is possible to provide the light-emitting device 1 that can suppress a decrease in luminous efficiency even when manufactured in the atmosphere and can be manufactured in the atmosphere.

Note that in the present embodiment, the method for forming the light-emitting element 3 on the substrate 2 in step S1 can be any of various known methods, and is not limited to a specific method.

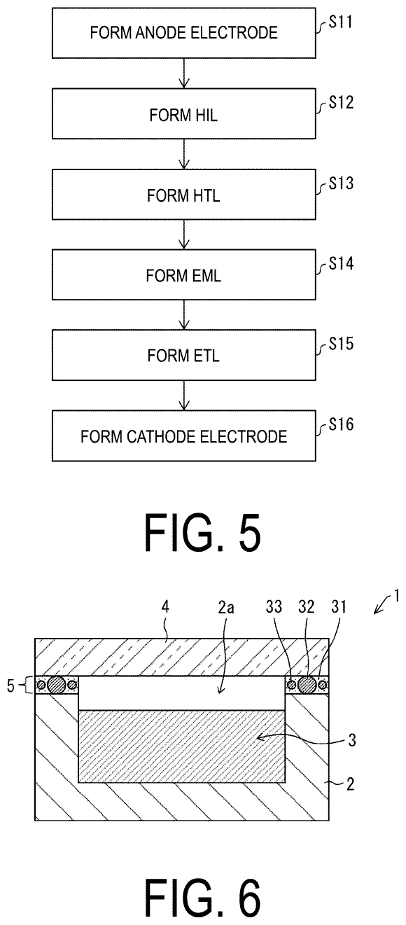

FIG. 5 is a flowchart illustrating an example of a method for forming the light-emitting element 3 illustrated in FIG. 2.

When forming the light-emitting element 3 illustrated in FIG. 2 as the light-emitting element 3, first, as illustrated in FIG. 5, the anode electrode 11 is formed on the substrate 2 (step S11, anode electrode forming step). Subsequently, the HIL 21 is formed (step S12, HIL forming step). Subsequently, the HTL 22 is formed (step S13, HIL forming step). Subsequently, the EML 23 is formed (step S14, EML forming step). Subsequently, the ETL 24 is formed (step S15). Subsequently, the cathode electrode 12 is formed (step S16, cathode electrode forming step).

Examples of deposition methods of the anode electrode 11 and the cathode electrode 12 include physical vapor deposition (PVD) such as a vacuum vapor deposition technique, sputtering, electron beam (EB) deposition, and ion plating, and chemical vapor deposition (CVD).

For example, a vacuum vapor deposition technique, a spin coating method, and an ink-jet method can be used to deposit the HIL 21, the HTL 22, and the ETL 24. When the EML 23 is a QD light-emitting layer containing QDs 23a as described above, the EML 23 can be formed by applying QD dispersion containing QDs 23a and a solvent, and then drying the applied QD dispersion. The QD dispersion may contain known ligands as a dispersant.

As illustrated in FIG. 1, for example, when a cover member having a recessed shape in which the recessed portion 4a is provided in a central portion is used as the cover member 4, the cover member 4 is placed to have an inverted recessed shape so that the light-emitting element 3 is located in the recessed portion 4a when the light-emitting element 3 is covered with the cover member 4. The cover member 4 includes, at the periphery thereof, a side wall 4al that forms the recessed portion 4a. The cover member 4 is bonded to the substrate 2 on a lower surface of the side wall 4al forming the recessed portion 4a with the adhesive layer 5 interposed therebetween. Thus, in step S2, for example, the adhesive layer material is applied to the lower surface of the side wall forming the recessed portion 4a in the peripheral portion of the cover member 4, which is the joint surface of the cover member 4 with the substrate 2. However, the adhesive layer material is not limited to being applied to the lower surface of the side wall of the cover member 4, but may be applied to the substrate 2.

In the present embodiment, as an example of the cover member 4, a cover member in which a depth of the recessed portion 4a, in other words, a step formed by a bottom wall and the side wall 4a1 forming the recessed portion 4a is 0.3 mm, is used. However, the step may be appropriately set according to the size of the light-emitting element 3 so that the light-emitting element 3 can be placed in the recessed portion 4a, and is not limited to a particular numerical value.

The adhesive layer material is prepared in advance by mixing the curable adhesive 31, the spacer 32, and the oxygen adsorbent 33. Note that the adhesive layer material may contain components other than the curable adhesive 31, the spacer 32, and the oxygen adsorbent 33, such as a solvent. The preparation of the adhesive layer material may be performed before step S1 or may be performed in parallel with step S1 as long as the adhesive layer material is prepared before step S2.

Concentrations of the above components in the adhesive layer material and a viscosity of the adhesive layer material are not limited as long as the adhesive layer material is prepared so that the adhesive layer 5 having a desired layer thickness can be obtained and the adhesive layer material has a viscosity capable of being applied, depending on a method for applying the adhesive layer material.

The method for applying the adhesive layer material in step S2 is not limited to a specific method. For example, a dispenser method may be used, or a printing method, an inkjet method, or the like may be used.

In step S3, the curable adhesive 31 is cured by, for example, irradiating the curable adhesive 31 with UV using a UV irradiation device. Note that the curing conditions of the curable adhesive 31 may be appropriately set according to, for example, a type and an amount of the curable adhesive 31 so that the curable adhesive 31 is cured, and are not limited to particular conditions.

### EXAMPLES

Next, effects of the light-emitting device 1 according to the present embodiment will be described using Examples and Comparative Examples. However, the light-emitting device 1 according to the present embodiment is not limited to Examples below.

### External Quantum Efficiency

Note that in Examples and Comparative Examples below, the external quantum efficiency (No (exe)) was evaluated as the number of photons (Np) extracted per unit surface area of a light-emitting element relative to the number of carriers (Ne) injected into the light-emitting element sealed in a cell prepared as a light-emitting device for evaluation, as shown in the following equations.

$$Np = λ / hc \times P \times 1 / S ( 1 / {m}^{2} )$$

$$Ne = I / e \times 1 / S ( 1 / {m}^{2} )$$

$${N}_{φ ( exe )} = Np / Ne \times 100 = ( P \times λ \times e ) / ( hc \times I ) \times 100 ( \% )$$

Note that in the equations, I represents a current (A), P represents a light intensity (measured light amount (W)), S represents an area of the light-emitting element (element area (m²)), λ represents an emission peak wavelength (m), e represents an elementary charge (A·s), h represents Planck's constant (J·s), and c represents a speed of light (m·s⁻¹).

The current (I) was measured using a Keithley's Standard Series 2400 Source Measure Unit. The light intensity (P) was measured using a light intensity meter (model number: BM-5A) manufactured by TOPCON TECHNOHOUSE CORPORATION. The area of the light-emitting element was 4×10⁻⁶ (m²). The emission peak wavelength (λ) was 536 (nm). The Planck's constant was 6.626×10⁻³⁴ J·s. The elementary charge (e) was 1.602×10⁻¹⁹ A·s. The speed of light (c) was 2.998×10⁸ (m·s⁻¹).

### Reliability Test

A time until the adhesive layer of the cell prepared as the light-emitting device for evaluation peeled off was measured in an environment of 35° C. and 80% humidity, and reliability was evaluated based on the time until the adhesive layer peeled off.

### Example 1

An adhesive layer material containing 10 parts by weight of a curable adhesive, 0.5 parts by weight of a spacer, 0.5 parts by weight of an oxygen adsorbent, and 0.1 parts by weight of a photopolymerization initiator was applied to a cover glass, and the cover glass was bonded so as to cover the light-emitting element formed on the substrate.

The light-emitting element used was a light-emitting element measuring 1.5 cm×1.5 cm in a plan view and containing 2.15×10⁻⁵ g (0.02154 mg) of QDs as the light-emitting material. The cover glass used was a recessed cover glass measuring 2.0 cm×2.0 cm in a plan view, formed of 0.5 cm thick glass, and having a recessed portion measuring 1.5 cm×1.5 cm in a plan view. A bisphenol epoxy resin was used as the curable adhesive. Spherical monodispersed silica particles having a diameter of 12 μm were used as the spacer. BHT was used as the oxygen adsorbent.

Subsequently, the adhesive layer material was cured by irradiating it with UV at 600 mJ/cm² using a UV irradiation device. Thus, an adhesive layer having a length of 2.0 cm, a width of 0.5 cm, and a height of 12 μm was formed between the substrate and the cover glass so as to surround the four sides of the light-emitting element. Note that the above series of operations were performed in the atmosphere.

Thus, as the light-emitting device for evaluation, a cell in which the light-emitting element was sealed with the substrate, the cover glass, and the adhesive layer that bonded the peripheral portion of the cover glass to the substrate was produced in the atmosphere. Subsequently, the external quantum efficiency of the produced cell was measured and a reliability test was performed.

### Examples 2 to 7

Cells as light-emitting devices for evaluation were produced in the atmosphere by the same operation as in Example 1, except that the amounts of the oxygen adsorbents relative to the curable adhesive were changed as shown in Table 1 below. Note that light-emitting elements having the same configuration as in Example 1 were used as the light-emitting elements. Thereafter, the external quantum efficiency of each of the produced cells was measured and a reliability test was conducted.

### Comparative Example 1

A cell as a light-emitting device for evaluation was produced in the atmosphere by performing the same operations as in Example 1, except that the oxygen adsorbent and the spacer were not added to the curable adhesive. Note that a light-emitting element having the same configuration as in Example 1 was used as the light-emitting element. Thereafter, the external quantum efficiency of the produced cell was measured and a reliability test was conducted.

### Comparative Example 2

A cell as a light-emitting device for evaluation was produced in the atmosphere by performing the same operations as in Example 1, except that the oxygen adsorbent was not added to the curable adhesive. Note that a light-emitting element having the same configuration as in Example 1 was used as the light-emitting element. Thereafter, the external quantum efficiency of the produced cell was measured and a reliability test was conducted.

### Reference Example 1

A cell as a light-emitting device for evaluation was produced in the atmosphere by performing the same operations as in Example 1, except that the oxygen adsorbent and the spacer were not added to the curable adhesive and a series of operations were performed in an inert atmosphere. Note that a light-emitting element having the same configuration as in Example 1 was used as the light-emitting element. Thereafter, the external quantum efficiency of the produced cell was measured and a reliability test was conducted.

A combination ratio (compounding ratio) of the curable adhesive, the oxygen adsorbent, and the spacer, the cell production environment, the external quantum efficiency of the produced cell, and the result of the reliability test in each of Examples 1 to 7, Comparative Examples 1 and 2, and Reference Example 1 are summarized in Table 1.

TABLE 1

| | | | | | Amount of | | |
|---|---|---|---|---|---|---|---|
| | | | | Photopoly- | oxygen | | |
| | Curable | | Oxygen | merization | adsorbent | | |
| | adhesive | Spacer | adsorbent | initiator | relative to | External | Reliability |
| | (parts | (parts | (parts | (parts | curable | quantum | test |
| | by | by | by | by | adhesive | efficiency | (35° |
| | weight) | weight) | weight) | weight) | (wt. %) | (%) | C./80%) |
| Example 1 | 10 | 0.5 | 0.5 | 1 | 5 | 8.5 | 910 |
| Example 2 | 10 | 0.5 | 1 | 1 | 10 | 8.8 | 930 |
| Example 3 | 10 | 0.5 | 2 | 1 | 20 | 9.3 | 1000 |
| Example 4 | 10 | 0.5 | 3 | 1 | 30 | 9.1 | 950 |
| Example 5 | 10 | 0.5 | 4 | 1 | 40 | 9.0 | 850 |
| Example 6 | 10 | 0.5 | 0.3 | 1 | 3 | 8.2 | 900 |
| Example 7 | 10 | 0.5 | 5 | 1 | 50 | 8.9 | 700 |
| Comparative | 10 | — | — | 1 | — | 7.1 | 900 |
| Example 1 | | | | | | | |
| Comparative | 10 | 0.5 | — | 1 | — | 7.2 | 900 |
| Example 2 | | | | | | | |
| Reference | 10 | — | — | 1 | — | 9.5 | 900 |
| Example 1 | | | | | | | |

As can be seen from Table 1, when cells are produced in the atmosphere without using an oxygen adsorbent in the adhesive layer as in Comparative Examples 1 and 2, the external quantum efficiency is greatly reduced compared to Reference Example 1 in which the same operations as in Comparative Example 1 were carried out in an inert atmosphere.

However, as described above, in order to industrially manufacture light-emitting devices in an inert atmosphere, investment in equipment is required, and adjustment and maintenance of a working environment are required, which increases manufacturing costs.

However, according to the present embodiment, there is no need to carry out work in such an inert atmosphere. According to the present embodiment, by containing the oxygen adsorbent in the adhesive layer as in Examples 1 to 7, it is possible to suppress or prevent a decrease in external quantum efficiency when cells are produced in the atmosphere, compared to the case where the oxygen adsorbent is not contained in the adhesive layer as in Comparative Examples 1 and 2.

From the results shown in Table 1, it can be seen that the amount of the oxygen adsorbent relative to the curable adhesive in the adhesive layer may be, for example, 3 wt. % or more, but is preferably from 5 wt. % to 40 wt. %, and more preferably from 20 wt. % to 40 wt. %.

As can be seen from Table 1, when the amount of the oxygen adsorbent relative to the curable adhesive is increased, a decrease in external quantum efficiency when the cell is produced in the atmosphere can be suppressed, but the reliability test result tends to be poor. As can be seen from Table 1, when the amount of the oxygen adsorbent relative to the curable adhesive in the adhesive layer is from 5 wt. % to 40 wt. %, it is possible to obtain a light-emitting device that is more effective in suppressing or preventing a decrease in external quantum efficiency, can be manufactured in the atmosphere, and has higher reliability. In particular, when the amount of the oxygen adsorbent relative to the curable adhesive is from 20 wt. % to 40 wt. %, it is possible to obtain a light-emitting device that can obtain external quantum efficiency almost equivalent to that obtained when a cell is produced in an inert atmosphere, has a higher effect of suppressing or preventing a decrease in external quantum efficiency, can be manufactured in the atmosphere, and has even higher reliability.

As described above, in the present embodiment, light-emitting elements having the same configuration were used in Examples 1 to 7, Comparative Examples 1 and 2, and Reference Example 1. Specific values of the external quantum efficiencies and the reliability test results depend on the performance of the light-emitting element and thus vary depending on the configuration of the light-emitting element, but the general trends are the same as those described above.

Thus, according to the present embodiment, since the adhesive layer contains the curable adhesive, the spacer, and the oxygen adsorbent, it is possible to provide a light-emitting device that can suppress a decrease in luminous efficiency even when manufactured in the atmosphere and can be manufactured in the atmosphere, and a method for manufacturing the light-emitting device.

### First Modified Example

Note that in the present embodiment, description has been given using a case where the light-emitting element 3 is a QLED as an example. However, the present embodiment is not limited thereto, and the light-emitting element 3 may be an OLED.

When the light-emitting element 3 is an OLED, the EML 23 is an organic light-emitting layer and is made of an organic light-emitting material such as a low molecular weight fluorescent dye or a metal complex. Note that the organic light-emitting material may be a phosphorescent light-emitting material or a fluorescence light-emitting material. As the organic light-emitting material, an organic light-emitting material capable of emitting light of a desired color is used. When the light-emitting element 3 is an OLED, the EML 23 can be formed by, for example, vapor deposition.

### Second Modified Example

In the present embodiment, the light-emitting device 1 is described as a top emission light-emitting device in which light is emitted from the cover member 4 side. However, the present embodiment is not limited thereto, and the light-emitting device 1 may be a bottom emission light-emitting device in which light is emitted from the substrate 2 side, or may be a double-sided emission light-emitting device in which light is emitted from both the cover member 4 side and the substrate 2 side.

When the light-emitting device 1 is a bottom emission light-emitting device or a double-sided emission light-emitting device, the substrate 2 is a substrate having light transmitting property including a base of, for example, glass or a resin having light transmitting property. When the light-emitting device 1 is a bottom emission light-emitting device, the cover member 4 may be made of, for example, a reflective material such as metal or a light blocking material.

In any cases, since the adhesive layer 5 of the light-emitting device 1 contains the oxygen adsorbent 33, light transmission is not hindered as in the case where an oxygen adsorbent is provided in the space in which the light-emitting element is sealed, and the luminescence observation is not hindered.

Since the adhesive layer 5 contains the oxygen adsorbent 33, the light-emitting device 1 can be a bottom emission light-emitting device, or can be a top emission light-emitting device or a double-sided emission light-emitting device, as described above. Thus, the light-emitting device 1 has high flexibility in selecting the luminescence observation direction, and can be manufactured as various types of light-emitting devices, unlike the case where the oxygen adsorbent is provided in the space in which the light-emitting element is sealed.

### Third Modified Example

FIG. 6 is a cross-sectional view illustrating an example of a schematic configuration of the light-emitting device 1 according to this modified example.

In FIG. 1, an example is illustrated in which the cover member 4 has the recessed portion 4a, but the present embodiment is not limited thereto, and as illustrated in FIG. 6, the substrate 2 may have a recessed portion 2a in which the light-emitting element 3 is placed. In this case, the light-emitting element 3 is placed in the recessed portion 2a of the substrate 2.

The substrate 2 having the recessed portion 2a may be a so-called recessed substrate in which a recessed portion called a trench is provided in a substrate serving as a base substrate, or may be a substrate in which a protruding portion called a dam is formed on a surface of the substrate 2. The dam is formed in a frame region surrounding a display region, for example, in a frame shape along the periphery of the display region, so as to surround the display region. As a material of the dam, various known dam materials having moisture-proof properties can be used.

When the substrate 2 has the recessed portion 2a as illustrated in FIG. 6, a plate-shaped cover member can be used as the cover member 4. Note that when the recessed portion 2a is provided in the substrate 2, the recessed portion 2a may be formed only in the display region where the light-emitting element 3 is located, or may be formed over the entire region of the substrate 2 excluding the peripheral portion and including a terminal portion so that the cover member 4 can cover the terminal portion and the entire display region of the substrate 2.

When the recessed portion 2a is formed only in the display region in the substrate 2, in other words, in a region excluding the terminal portion TS, the terminal portion can be formed to be bendable by using a flexible material for the substrate 2 or the terminal portion. In this case, a bending portion may be provided between the terminal portion and the display region.

On the other hand, when the cover member 4 has the recessed portion 4a as described above, the plate-shaped substrate 2 can be used as illustrated in FIG. 1. As the cover member 4, for example, a cap-shaped transparent cover member called a cover glass, which has been conventionally and commonly used, can be used. Thus, when the cover member 4 has the recessed portion 4a as described above, manufacture becomes easy, and the process and the configuration can be simplified.

Note that the recessed portions may be formed in both of the substrate 2 and the cover member 4. By providing the recessed portion at least one of the substrate 2 and the cover member 4 as described above, the thickness of the adhesive layer 5 can be reduced. This eliminates the need for the spacer 32 having a large thickness, and the freedom in selecting the spacer 32 increases.

Even when the cover member 4 has the recessed portion 4a, when the cover member 4 is formed so as to cover only the display region in the substrate 2, in other words, the region excluding the terminal portion, the terminal portion can be formed to be bendable by using a flexible material for the substrate 2 or the terminal portion.

### Fourth Modified Example

In the present embodiment, as described above, an example is described in which a square-shaped light-emitting element is used as the light-emitting element 3, but the shape of the light-emitting element 3 is not limited thereto, and can be any of various shapes. The shape of the cover member 4 and the shape of the recessed portion 2a or the recessed portion 2a are not limited to the square shape in a plan view.

### Second Embodiment

Differences from the first embodiment will be described in the present embodiment. Note that, for convenience of description, constituent elements having the same function as the constituent elements described in the first embodiment are designated by the same reference numbers, and descriptions thereof are omitted.

In the first embodiment, the light-emitting device 1 in which one light-emitting element 3 is provided on the substrate 2 is described as an example. However, the light-emitting device according to the disclosure is not limited thereto, and it is sufficient that at least one light-emitting element 3 is provided on the substrate 2.

In the present embodiment, a case in which the light-emitting device according to the disclosure is a display device and a plurality of light-emitting elements 3 are provided on the substrate 2 will be described as an example. In the following, an example will be described in which the plurality of light-emitting elements 3 include a first light-emitting element, a second light-emitting element, and a third light-emitting element, the first light-emitting element includes, as the light-emitting layer (EML), a first light-emitting layer, the second light-emitting element includes, as the light-emitting layer, a second light-emitting layer having a light-emission peak wavelength differing from a light-emission peak wavelength of the first light-emitting layer, and the third light-emitting element includes, as the light-emitting layer, a third light-emitting layer having a light-emission peak wavelength differing from the light-emission peak wavelengths of the first light-emitting layer and the second light-emitting layer. However, the present embodiment is not limited thereto, and the plurality of light-emitting elements 3 may be light-emitting elements that emit light of the same color.

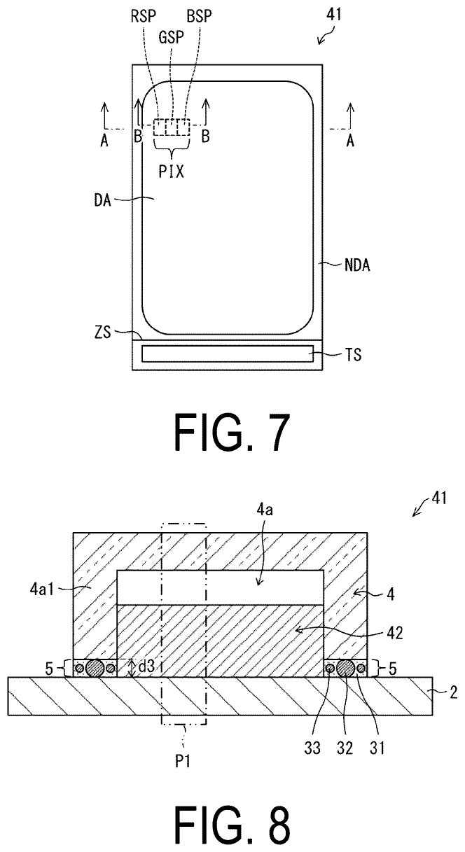

FIG. 7 is a plan view illustrating a schematic configuration of a display device 41 according to the present embodiment. Note that a cover member 4 and an adhesive layer 5 are omitted in FIG. 7.

As illustrated in FIG. 7, the display device 41 includes a frame region NDA and a display region DA.

A terminal portion TS is located at an end portion of the frame region NDA. The terminal portion TS is provided with an electronic circuit board (not illustrated) such as an integrated circuit (IC) chip and a flexible printed circuit board (FPC). Note that a bending portion ZS may be provided, as necessary, between the terminal portion TS and the display region DA, as illustrated in FIG. 7.

The display region DA of the display device 41 is provided with a plurality of pixels PIX, and each pixel PIX has subpixels SP, for example, a subpixel RSP (red subpixel) that emits red light, a subpixel GSP (green subpixel) that emits green light, and a subpixel BSP (blue subpixel) that emits blue light. Between the subpixels SP, a bank BK with insulating properties that partitions adjacent subpixels SP is provided as a pixel separation film.

Note that in the present embodiment, a case will be described as an example in which one pixel PIX is composed of the subpixel RSP, the subpixel GSP, and the subpixel BSP, but this is merely an example. For example, one pixel PIX may include a subpixel SP of another color in addition to the subpixel RSP, the subpixel GSP, and the subpixel BSP.

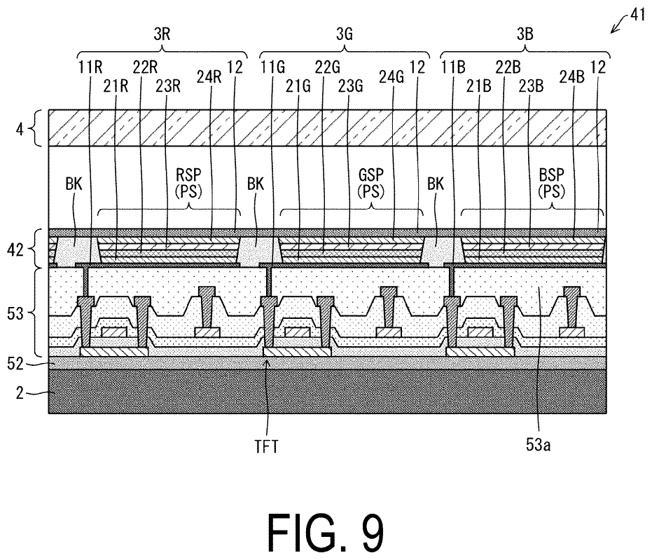

FIG. 8 is a cross-sectional view illustrating an example of a schematic configuration of the display device 41 according to the present embodiment. FIG. 9 is a cross-sectional view illustrating an example of a schematic configuration of the display region DA of the display device 41 illustrated in FIG. 8. Note that FIG. 8 corresponds to a cross sectional view taken along line A-A illustrated in FIG. 7. FIG. 9 is an enlarged view of a region P1 indicated by a two-dot chain line in FIG. 8, and corresponds to a cross-sectional view taken along line B-B illustrated in FIG. 7.

As illustrated in FIG. 8 and FIG. 9, the display device 41 has a configuration including an array substrate in which a thin film transistor layer (not illustrated) is formed on the substrate 2 as a drive element layer, and in a display region DA, a light-emitting element layer 42 including a plurality of light-emitting elements 3 having different light emission wavelengths is provided on the thin film transistor layer. The light-emitting element layer 42 is covered with a cover member 4 that covers at least the display region DA of the display device 41. Thus, the plurality of light-emitting elements 3 provided in the light-emitting element layer 42 are covered with the cover member 4. Also in the present embodiment, an adhesive layer 5 is provided between the substrate 2 and the cover member 4 to bond a peripheral portion of the cover member 4 to the substrate 2.

The display device 41 includes the plurality of light-emitting elements 3, including a light-emitting element 3R (red light-emitting element, first light-emitting element) that emits red light, a light-emitting element 3G (green light-emitting element, second light-emitting element) that emits green light, and a light-emitting element 3B (blue light-emitting element, third light-emitting element) that emits blue light. The subpixel RSP provided in the display region DA of the display device 41 includes the light-emitting element 3R. The subpixel GSP provided in the display region DA of the display device 41 includes the light-emitting element 3G. The subpixel BSP provided in the display region DA of the display device 41 includes the light-emitting element 3B.

The light-emitting element layer 42 includes the plurality of the light-emitting elements 3 provided for the subpixels SP, respectively, and has a structure in which the layers of these light-emitting elements 3 are layered on the substrate 2.

The substrate 2 functions as a support body for forming the layers of these light-emitting elements 3. In the present embodiment, an active matrix substrate (array substrate) in which a barrier layer 52 (undercoat layer) and a thin film transistor layer 53 including transistors TR are layered in this order on the substrate 2 is used as the substrate.

The substrate 2 is an insulating substrate serving as a base substrate, and as described above, may be, for example, a flexible substrate containing a resin such as polyimide as a main component or may be a rigid inorganic substrate such as a glass substrate. In the following, in order to make the display device 41 a display device in which a terminal portion TS is bendable, an example will be described in which a resin substrate (flexible substrate) made of a resin material such as polyimide is used as the substrate 2. However, the substrate 2 is not limited to the resin substrate. As described above, the substrate 2 may be, for example, a glass substrate. In this case, the barrier layer 52 may or may not be provided.

The barrier layer 52 is an inorganic insulating layer that prevents penetration of foreign matter such as water and oxygen. The barrier layer 52 may be composed of, for example, a silicon oxide film, a silicon nitride film, or a silicon oxynitride film, or a layered film of these, formed by CVD.

The thin film transistor layer 53 is a layer including thin film transistors as the transistors TR. In the thin film transistor layer 53, drive circuits are provided as subpixel circuits, including the transistors TR for driving the light-emitting elements 3 and various wiring lines. Note that the structure of the thin film transistor is well known, and thus a description thereof is omitted here. In FIG. 9, the thin film transistor including a semiconductor film as a channel is illustrated as having a top gate structure, but the thin film transistor may have a bottom gate structure.

A flattening film 53a is provided on a surface of the thin film transistor layer 53 to flatten surfaces of the transistors TR and the various wiring lines. The flattening film 53a can be made of a coatable organic material such as polyimide or acrylic resin.

The bending portion ZS can be formed, for example, by etching away an inorganic film (e.g., the barrier layer 52, the gate insulating film, or the like) of the bending portion ZS in the substrate 2 to form a groove, and then filling the groove with an organic film such as polyimide or acrylic resin. However, the configuration of the bending portion ZS and the method for forming the bending portion ZS are not limited thereto, and various known configurations and forming methods can be employed.

The light-emitting element layer 42 is provided above the substrate 2 in the display region DA. Therefore, the layers of the light-emitting elements 3 provided in the light-emitting element layer 42 are layered above the substrate 2 in the display region DA. In the present embodiment, as described above, the light-emitting element 3R, the light-emitting element 3G, and the light-emitting element 3B are provided as the light-emitting elements 3 in the light-emitting element layer 42.

Note that in the following, an example will be described in which the light-emitting element 3R, the light-emitting element 3G, and the light-emitting element 3B are all QLEDs and each has a configuration similar to that of the light-emitting element 3 illustrated in FIG. 2. However, the present embodiment is not limited thereto, and some of the light-emitting element 3R, the light-emitting element 3G, and the light-emitting element 3B may be QLEDs and the remaining some may be OLEDs. Furthermore, the light-emitting element 3R, the light-emitting element 3G, and the light-emitting element 3B may be OLEDs.

FIG. 9 illustrates an example in which these light-emitting elements 3 (the light-emitting element 3R, the light-emitting element 3G, and the light-emitting element 3B) each have a configuration similar to that of the light-emitting element 3 illustrated in FIG. 2.

The light-emitting element 3R illustrated in FIG. 9 includes an anode electrode 11R as the anode electrode 11, an HIL 21R as the HIL 21, an HTL 22R as the HTL 22, an EML 23R as the EML 23, and an ETL 24R as the ETL 24. The light-emitting element 3G illustrated in FIG. 9 includes an anode electrode 11G as the anode electrode 11, an HIL 21G as the HIL 21, an HTL 22G as the HTL 22, an EML 23G as the EML 23, and an ETL 24G as the ETL 24. The light-emitting element 3B illustrated in FIG. 9 includes an anode electrode 11B as the anode electrode 11, an HIL 21B as the HIL 21, an HTL 22B as the HTL 22, an EML 23B as the EML 23, and an ETL 24B as the ETL 24.

Note that FIG. 9 also illustrates, as an example, a case in which each light-emitting element 3 has a conventional structure. Thus the light-emitting element 3R illustrated in FIG. 9 has a configuration in which the anode electrode 11R, the HIL 21R, the HTL 22R, the EML 23R, the ETL 24R, and a cathode electrode 12 are layered in this order from a substrate 2 side. The light-emitting element 3G illustrated in FIG. 9 has a configuration in which the anode electrode 11G, the HIL 21G, the HTL 22G, the EML 23G, the ETL 24G, and the cathode electrode 12 are layered in this order from the substrate 2 side. The light-emitting element 3B illustrated in FIG. 9 has a configuration in which the anode electrode 11G, the HIL 21B, the HTL 22B, the EML 23B, the ETL 24B, and the cathode electrode 12 are layered in this order from the substrate 2 side.

Although not illustrated, when the light-emitting element 3R, the light-emitting element 3G, and the light-emitting element 3B have an inverted structure, the layering order of the function layers is reversed from that in FIG. 9. Also in this embodiment, the light-emitting element 3R, the light-emitting element 3G, and the light-emitting element 3B may have a configuration in which at least one of the function layers other than the EML is not provided, or may have a function layer other than the above function layers.

As illustrated in FIG. 9, each anode electrode, which is a lower layer electrode, and the function layers in each subpixel SP are separated in an island by the bank BK for each subpixel SP. On the other hand, the cathode electrode 12, which is an upper layer electrode, is not separated by the bank BK, but is formed as a common layer common to all the subpixels SP. Therefore, in the present embodiment, the anode electrode 11R, the anode electrode 11G, and the anode electrode 11B are patterned anode electrodes formed in an island shape. The anode electrode 11R, the anode electrode 11G, and the anode electrode 11B in the respective subpixels SP are electrically connected to the transistors TR in the thin film transistor layer 53, respectively. On the other hand, the cathode electrode 12 is a common cathode electrode common to all the subpixels SP.

Note that the bank BK is used as a pixel separation film as described above, and is also used as an edge cover that covers edges of the patterned lower layer electrodes. Thus, as illustrated in FIG. 9, the edges of the anode electrode 11R, the anode electrode 11G, and the anode electrode 11B are each covered with the bank BK.

The bank BK is formed by applying a coatable photosensitive organic material such as polyimide or acrylic resin, and then patterning the applied photosensitive organic material by photolithography. The bank BK may contain a light absorbing agent such as carbon black.

In a method for manufacturing the display device 41 according to the present embodiment, in step S11 illustrated in FIG. 5, the anode electrode 11R, the anode electrode 11G, and the anode electrode 11B are formed as the anodes 11 above the substrate 2. Subsequently, before performing step S12, the bank BK is formed. In step S12, the HIL 21R, the HIL 21G, and the HIL 21G are formed as the HILs 21. In step S13, the HTL 22R, the HTL 22G, and the HTL 22G are formed as the HTLs 22. Step S14 includes a red EML forming step of forming the EML 23R, a green EML forming step of forming the EML 23G, and a blue EML forming step of forming the EML 23B. When the EML 23R, the EML 23G, and the EML 23B are QD light-emitting layers containing QDs 23a, red QDs that emit red light are used as the QDs 23a in the EML 23R. Green QDs that emit green light are used as the QDs 23a in the EML 23G. Blue QDs that emit blue light are used as the QDs 23a in the EML 23B. As described above, the QDs 23a can have light emission wavelengths changed in various ways depending on, for example, particle sizes and compositions thereof. Note that in step S14, an order of the red EML forming step, the green EML forming step, and the blue EML forming step is not limited. In step S15, the ETL 24R, the ETL 24G, and the ETL 24G are formed as the ETLs 24. In step S16, the cathode electrode 12 provided in common to all the subpixels SP is formed as the cathode electrode 12.

In the present embodiment, the anode electrode 11R, the anode electrode 11G, and the anode electrode 11B are formed in the same step using the same material. The HIL 21R, the HIL 21G, and the HIL 21G may be formed in the same step using the same material, or any two of these may be formed in the same step using the same material and the remaining one may be formed in a different step using a different material. Similarly, the HTL 22R, the HTL 22G, and the HTL 22G may be formed in the same step using the same material, or any two of these may be formed in the same step using the same material and the remaining one may be formed in a different step using a different material. The ETL 24R, the ETL 24G, and the ETL 24G may be formed in the same step using the same material, or any two of these may be formed in the same step using the same material and the remaining one may be formed in a different step using a different material.

The light-emitting element layer 42 is covered with the cover member 4. Thus, as described above, the cover member 4 covers the plurality of light-emitting elements 3 provided in the light-emitting element layer 42. FIG. 8 illustrates an example in which the cover member 4 has a recessed portion 4a. The plurality of light-emitting elements 3 are each arranged in the recessed portion 4a of the cover member 4.

However, this is not the only possible configuration for the present embodiment. For example, a recessed portion 2a may be provided in the substrate 2. In this case, for example, a recessed substrate having a recessed portion may be used as the substrate 2 or a dam may be provided on a surface of the substrate 2 to provide the recessed portion 2a in the substrate 2.

Also in the present embodiment, the amount of the oxygen adsorbent 33 relative to the curable adhesive 31 in the adhesive layer 5 is preferably from 5 wt. % to 40 wt. %. In this case, as the light-emitting device according to the present embodiment, it is possible to obtain the display device 41 that is more effective in suppressing or preventing a decrease in external quantum efficiency, can be manufactured in the atmosphere, and has higher reliability. When the amount of the oxygen adsorbent 33 relative to the curable adhesive 31 is from 20 wt. % to 40 wt. %, it is possible to obtain the display device 41 that can obtain an external quantum efficiency that is almost equivalent to that obtained when a cell is produced in an inert atmosphere, has an even higher effect of suppressing or preventing a decrease in external quantum efficiency, can be produced in the atmosphere, and has even higher reliability.

In the present embodiment, the adhesive layer 5 preferably contains the oxygen adsorbent 33 in an amount at least 2.7 times, and more preferably contains the oxygen adsorbent 33 in an amount at least 4.4 times, the total weight of the light-emitting materials of all the light-emitting elements 3 in the light-emitting element layer 42. That is, in the present embodiment, the adhesive layer 5 preferably contains the oxygen adsorbent 33 in the above ratio to the total weight of the light-emitting materials of the plurality of light-emitting elements 3 covered with the cover member 4.

By containing the oxygen adsorbent 33 in the adhesive layer 5 in an amount at least 2.7 times the weight of the light-emitting materials in the plurality of light-emitting elements 3, oxidation of the light-emitting materials can be sufficiently suppressed even when the display device 41 is manufactured in the atmosphere, and the display device 41 having a higher effect of suppressing or preventing a decrease in external quantum efficiency can be obtained. In addition, by containing the oxygen adsorbent 33 in the adhesive layer 5 in an amount at least 4.4 times the weight of the light-emitting materials in the plurality of light-emitting elements 3, the display device 41 can be obtained that has a higher effect of suppressing oxidation of the light-emitting materials and an even higher effect of suppressing or preventing a decrease in external quantum efficiency.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

### REFERENCE SIGNS LIST

1 Light-emitting device
2 Substrate
2a, 4a Recessed portion
3, 3B, 3G, 3R Light-emitting element
4 Cover member
5 Adhesive layer
41 Display device (light-emitting device)
31 Curable adhesive
32 Spacer
33 Oxygen adsorbent
23a QD

1. A light-emitting device comprising:
a substrate;
at least one light-emitting element provided on the substrate;
a cover member configured to cover the at least one light-emitting element; and
an adhesive layer provided between the substrate and the cover member, surrounding the at least one light-emitting element, and configured to bond a peripheral portion of the cover member to the substrate,
wherein the adhesive layer contains a curable adhesive, a spacer, and an oxygen adsorbent.

2. The light-emitting device according to claim 1,
wherein at least one of the substrate and the cover member has a recessed portion, and
the at least one light-emitting element is located in the recessed portion.

3. The light-emitting device according to claim 2,
wherein the cover member has the recessed portion.

4. The light-emitting device according to claim 1,
wherein the oxygen adsorbent is a phenol-based oxygen adsorbent.

5. The light-emitting device according to claim 1,
wherein the oxygen adsorbent is at least one selected from the group consisting of dibutylhydroxytoluene, 2,6-di-tert-butyl-4-methoxyphenol, 3-tert-butyl-4-hydroxyanisole, hydroquinone, hydroquinone monomethyl ether, and 4-tert-butylcatechol.

6. The light-emitting device according to claim 1,
wherein the oxygen adsorbent contains dibutylhydroxytoluene.

7. The light-emitting device according to claim 1,
wherein an amount of the oxygen adsorbent relative to the curable adhesive in the adhesive layer is from 5 wt. % to 40 wt. %.

8. The light-emitting device according to claim 1,
wherein an amount of the oxygen adsorbent relative to the curable adhesive in the adhesive layer is from 20 wt. % to 40 wt. %.

9. The light-emitting device according to claim 1,
wherein the adhesive layer contains the oxygen adsorbent in an amount at least 2.7 times a weight of a light-emitting material in the at least one light-emitting element.

10. The light-emitting device according to claim 9,
wherein the at least one light-emitting element contains quantum dots as the light-emitting material.

11. The light-emitting device according to claim 1,
wherein the light-emitting device is a display device,
the at least one light-emitting element comprises a plurality of light-emitting elements, and
the plurality of light-emitting elements are provided on the substrate.

12. A method for manufacturing a light-emitting device, the light-emitting device including
a substrate,
at least one light-emitting element provided on the substrate,
a cover member having light transmitting property and configured to cover the at least one light-emitting element, and
an adhesive layer provided between the substrate and the cover member, surrounding the at least one light-emitting element, and configured to bond a peripheral portion of the cover member to the substrate, the method comprising:
applying an adhesive layer material containing a curable adhesive, a spacer, and an oxygen adsorbent to the substrate or the cover member in the atmosphere; and
bonding the substrate and the cover member in the atmosphere with an adhesive layer made of the adhesive layer material as the adhesive layer interposed between the substrate and the cover member by curing the curable adhesive.
